(19) United States
(12) Patent Application Publication
(10) Pub. No.: US 2015/0346037 A1
(43) Pub. Date: Dec. 3, 2015

(54) INTEGRATED TEMPERATURE SENSOR

(71) Applicant: Infineon Technologies AG, Neubiberg (DE)

(72) Inventors: Andreas Kiep, Munich (DE); Stefan Willkofer, Munich (DE); Andreas Strasser, Regensburg (DE)

(21) Appl. No.: 14/290,683

(22) Filed: May 29, 2014

(51) Int. Cl. G01K 7/01; H01L 35/34; H01L 21/308

(52) U.S. Cl. CPC G01K 7/01; H01L 21/308; H01L 35/34

(57) ABSTRACT

An integrated temperature sensor comprising a barrier layer connecting at least two conductive elements, wherein the barrier layer has a positive temperature coefficient.

### BACKGROUND

Embodiments of the present disclosure relate to a temperature sensor that may preferably be embedded into an semiconductor.

### SUMMARY

A first embodiment relates to an integrated temperature sensor comprising:
a barrier layer connecting at least two conductive elements,
wherein the barrier layer has a positive temperature coefficient.

A second embodiment relates to a circuit comprising
an electronic switching element,
an integrated temperature sensor, which is arranged in the vicinity of the electronic switching element,
wherein the integrated temperature sensor comprises
   a barrier layer connecting at least two conductive elements,
   wherein the barrier layer has a positive temperature coefficient.

A third embodiment relates to a method for manufacturing an integrated temperature sensor, the method comprising
structuring a barrier layer that connects at least two conductive elements,
wherein the barrier layer has a positive temperature coefficient.

### BRIEF DESCRIPTION OF THE DRAWINGS

Embodiments are shown and illustrated with reference to the drawings. The drawings serve to illustrate the basic principle, so that only aspects necessary for understanding the basic principle are illustrated. The drawings are not to scale. In the drawings the same reference characters denote like features.

FIG. 1 shows a metal stack a barrier layer below the metal stack and an oxide or wafer being arranged below the barrier layer, wherein a photo resist is applied on top of the metal stack to mask two metal pads;

FIG. 2 shows the two metal pads after etching, wherein another photo resist is applied on top of the metal pads and on top of a barrier layer that connects the two metal pads;

FIG. 3 shows the embedded temperature sensor as the barrier layer connecting the two metal pads;

FIG. 4 shows a top view corresponding to the processing step visualized in FIG. 2;

FIG. 5 shows a top view corresponding to the processing step visualized in FIG. 3 without depicting the oxide or wafer;

FIG. 6 shows a three-dimensional representation of this structure (without the oxide or wafer);

FIG. 7 shows an exemplary circuit diagram comprising two transistors that are combined with a resistor as temperature dependent device in a unit 701;

FIG. 8 shows a schematic diagram comprising a unit with two transistors and a resistor as a temperature dependent device with an attached circuitry to determine a temperature-compensated current or voltage and act accordingly;

FIG. 9 shows a circuitry of an IGBT half-bridge arrangement comprising a high-side unit and a low-side unit, both units being controlled via a microcontroller in an isolated manner;

FIG. 10 shows a schematic diagram of the drivers employed in FIG. 9;

FIG. 11A to FIG. 11C show several exemplary embodiments of embedded temperature sensors.

### DETAILED DESCRIPTION OF THE PREFERRED EMBODIMENTS

An example described herein refers to an on-chip temperature measurement means (also referred to as temperature sensor or temperature sensing means). Such temperature sensor may be provided by a conductive layer with a positive temperature coefficient, which may in particular be integrated in a semiconductor, in particular a power semiconductor (such as, e.g., a MOSFET, an IGBT, a JFET or a diode). Such example may allow a more precise temperature measurements in a cost efficient manner.

In an example, the conductive layer (with positive temperature coefficient) may become part of a manufacturing process of the semiconductor. An exemplary solution of such temperature sensor may be directed to an intrinsic temperature compensation of a sense current or sense voltage itself, preferably inside the semiconductor together with a current sense field. Hence, no additional compensation and no further complex signal processing is required.

It is in particular suggested to utilize a layer, in particular a thin metallic layer, that is applied during an existing manufacturing step. Such utilization may comprise structuring the layer. For that purpose, at least one layer may be used that serves as a barrier layer below a metallic trace. The barrier layer may be provided on top of a substrate, e.g., a silicon or silicon-oxide substrate. The metallic trace may in particular comprise any of the following materials: aluminum, copper, silicon, etc. or any combination thereof.

The barrier layer may comprise at least one of the following: wolfram (tungsten), titanium, titanium-nitride, wolfram-titanium, tantalum, tantalum-nitride. The layer may in particular comprise any thin metallic (barrier) layer.

Metals predominately have a (rather high) positive temperature coefficient Tk and may be deposited via sputtering, CVD (chemical vapor deposition), PVD (physical vapor deposition) or any similar approach.

The positive temperature coefficient may be largely unaffected by variations of the manufacturing process itself. It is an option to determine or even vary the resistance substantially independently from the temperature coefficient by, e.g., variations of the layout, layer thickness or the like.

Hence, the examples presented allow providing a temperature sensor which is provided on chip together with the semiconductor. The semiconductor may in particular be a power semiconductor.

The temperature sensor may be realized by structuring of thin metallic layers, wherein at least one of such layers may be part of a common manufacturing process of the semiconductor. Hence, the solution is an efficient way to alter an existing manufacturing process in order to provide a temperature sensor with high accuracy.

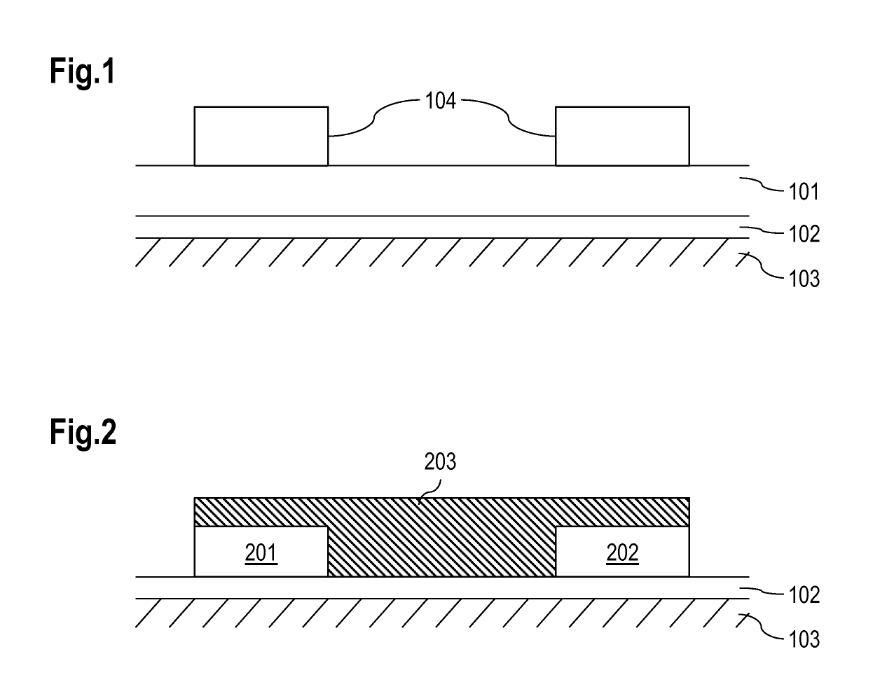

FIG. 1 shows a metal stack 101 comprising, e.g., AlSiCu, a barrier layer 102, e.g., a thin TiW layer, below the metal stack 101 and an oxide or wafer 103 below the barrier layer 102.

A photo resist 104 is applied on top of the metal stack 101 and serves as a mask to structure the metal stack 101. Such structuring of the metal stack 101 may be conducted via selective etching: the metal stack 101 that is not covered by the photo resist 104 is removed. Such selective etching may remove only the metal stack 101, not the barrier layer 102.

After the etching is completed, the photo resist 104 is removed revealing two metal pads 201 and 202 (the remaining metal from the metal stack 101). Another photo resist 203 is applied on top of the metal pads 201, 202 and on top of the barrier layer 102 that connects the two metal pads 201, 202 (see FIG. 2).

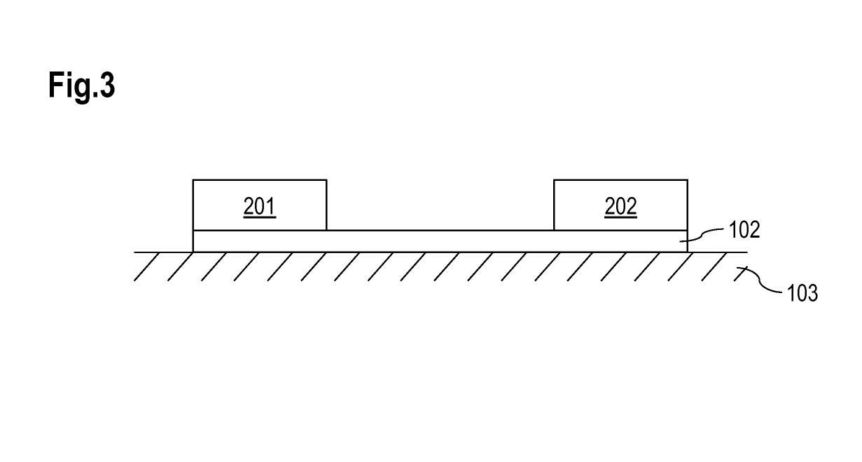

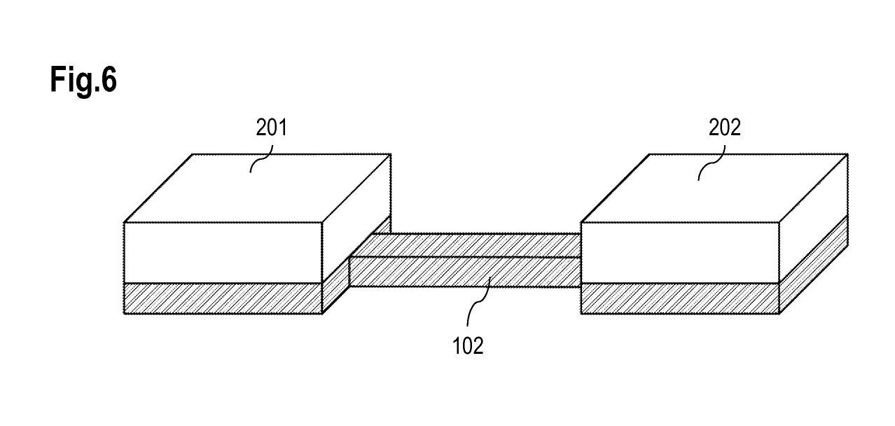

The barrier layer 102 not covered by the photo resist 203 is removed in a next (second) selective etching step. Then, the photo resist 203 is removed revealing the structure as shown in FIG. 3, i.e. the two metal pads 201 and 202, which are connected via the underlying barrier layer 102. FIG. 6 shows a three-dimensional representation of this structure (without the oxide 103).

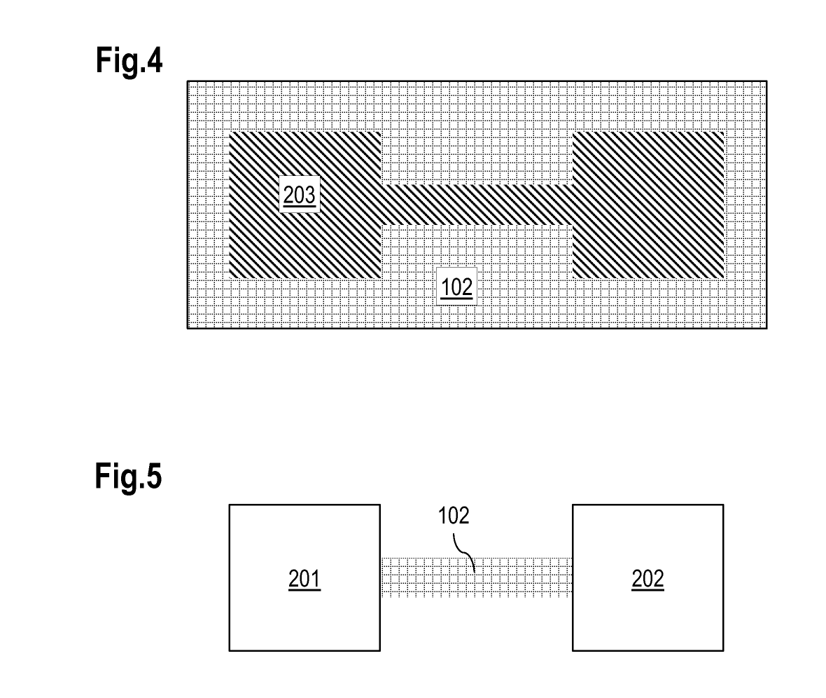

FIG. 4 shows a top view corresponding to the processing step visualized in FIG. 2. At this stage, the photo resist 203 and the barrier layer 102 are visible in the top view. FIG. 5 shows a top view corresponding to the processing step visualized in FIG. 3 without depicting the oxide or wafer 103. FIG. 5 corresponds to the three-dimensional representation of FIG. 6.

The photo resist 203 covers those areas that should not be removed when the barrier layer is etched. This allows providing thin barrier layers between the pads 201, 202 (or between any other conducting elements or paths).

The additional effort for producing such thin barrier layers may be limited to processing a single “photo resist layer”, i.e. applying the photo resist, expose the photo resist layer, developing the layer and removing the photo resist.

It is an option to electrically insulate the temperature sensor with the positive temperature coefficient from the semiconductor, e.g. via a field oxide. Providing an electrical insulation for the temperature sensor, the temperature sensor may be used in a half-bridge circuit, in particular with a high-side (high-voltage) switch of such half-bridge circuit.

An electrical isolation may be applied against at least one semiconductor terminal, e.g., a gate terminal, an emitter terminal, a source terminal, a collector terminal or a drain terminal. It is an option that the temperature sensor is electrically connected to one or more transistor terminals, which may reduce the pad or pin count and hence the overall costs.

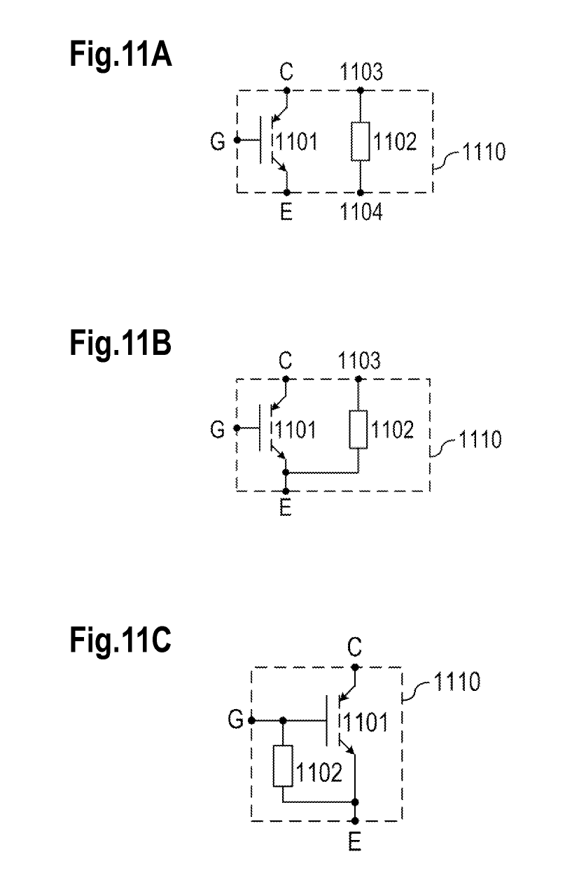

FIG. 11A shows an embedded temperature sensor 1102 that is electrically isolated from a transistor 1101 (comprising a gate terminal G, a collector terminal C and an emitter terminal E). In this scenario, two additional pads on the chip and two additional pins 1103, 1104 on a package 1110 are required.

FIG. 11B shows an alternative scenario of the package 1110, wherein one terminal of the temperature sensor 1102 is connected with the emitter (or source) of the transistor 1101. In this embodiment, the pad/pin count is reduced by one. A monitoring circuit (not shown) may “read” the sensor after the switching transition is finished, i.e. when the voltage spikes have substantially subsided via the pins E and 1103.

FIG. 11C shows yet another exemplary embodiment of the package 1110, wherein the terminals of the temperature sensors 1102 are connected with the transistor 1101, i.e. the first terminal of the temperature sensor 1102 is connected with the emitter (source) and the second terminal of the temperature sensor 1102 is connected with the gate of the transistor 1101. The monitoring circuit may “read” the sensor while a constant voltage is applied to the gate, i.e. while the transistor is turned ON. In case of an IGBT or MOSFET, the DC current flowing into the gate is much smaller than the current flowing through the temperature sensor. Hence, the current flowing through the temperature sensor, the resistance of the temperature sensor and the temperature of the temperature sensor may be determined.

In order to obtain a current information, a current sense field can be integrated inside a MOSFET, JFET or IGBT. The current sense field generates an electric current which is proportional to the load current, but smaller than the load current. The amount of the sense current may depend on the sense cell ratio (e.g., area ratio) and on the temperature. Such temperature dependency leads to a significant variation of the sense current, in particular in case the temperature of the MOSFET, JFET or IGBT is typically not known.

The current sensed may then be further processed to gain the actual current information, e.g., via means of sense resistors, operational amplifiers, Schmitt-triggers, etc.

The accuracy of the embedded current sense field varies over temperature. Especially in wide-temperature-range applications ranging from, e.g., −40° C. to 150° C., the accuracy changes may be significant, which may reduce the reliability and hence usability of such current sense mechanism for detection, protection, and/or control purposes.

For example, a short circuit detection circuit may typically be triggered at 420 A at a temperature of 150° C. compared to 550 A at a temperature of −40° C. Hence, the temperature shift may result in a current difference of 130 A. It is apparent that the short circuit current reaches 420 A sooner than it reaches 550 A. This translates into a longer short circuit pulse, a larger current amplitude, more power loss, and more short circuit energy, which may expose the transistor and the entire circuit to a significant amount of additional electrical and thermal stress due to the variation of temperature.

Examples provided in particular have an intrinsic temperature compensation of the sense current or sense voltage itself, preferably inside the semiconductor together with a current sense field. Hence, no additional compensation and no further complex signal processing is required.

The examples presented bear the advantage that a current can be sensed in short time, e.g., within microseconds, to allow for a fast (e.g., real-time) response. Such fast current sensing may be in particular advantageous for short circuit detection purposes. Also, the solution is efficient with regard to costs, required space and added power loss.

The solutions suggested can in particular be used for short circuit detection, overload protection and/or current mode control. Applications may be (but are not limited to) motor drives, air-conditioning compressors, pumps, etc. Such applications may be designed for significant temperature variations, e.g., in a range from 25° C. to 175° C.

According to an example, a temperature dependency of a transistor, e.g., IGBT or MOSFET may at least partially be compensated via an additional element, e.g., a resistor. This additional element (also referred to as temperature sensor) may be embedded in the transistor and it may be exposed to substantially the same temperature as the transistor. The additional element may be connected in series with a current sensor (e.g., a current sense resistor).

This allows compensating or at least reducing a temperature dependency of the circuitry comprising the transistor. The additional element may be a temperature dependent device also referred to as temperature compensating element or temperature sensor. Such temperature compensating element may at least partially compensate the current fluctuation that is based on temperature variations.

According to an example, the temperature dependent device may have a positive temperature coefficient, i.e. when the temperature increases a characteristics of the temperature dependent device increases as well. In case the temperature dependent device is a resistor, the resistance rises with an increase in temperature and the resistance falls with a decrease in temperature.

Preferably, the temperature dependent device, e.g., resistor with positive temperature coefficient, may be arranged in close proximity to the current sensor.

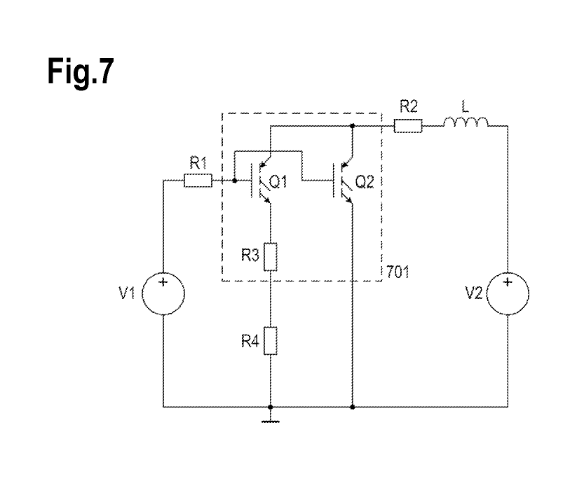

FIG. 7 shows an exemplary circuit diagram comprising two transistors Q1 and Q2 that are combined with a resistor R3 as temperature dependent device in a unit 701. The resistor R3 may have a positive temperature coefficient and it may be embedded with the transistors Q1 and Q2. The transistors Q1 and Q2 may be IGBTs or MOSFETs deployed on the same piece of silicon. The transistors Q1 and Q2 may share a functional unit that may be arranged on a common (e.g., emitter) area. The functional unit may comprise a multitude of functional elements that may be split according to a predetermined ratio, e.g., 1:10000. Hence, the transistor Q1 may act as the current sensor which carries a significantly smaller amount of current compared to the transistor Q2. The transistors Q1 and Q2 may be discrete transistors, wherein each of the transistor may have a split emitter pad or a split source pad. The transistors Q1 and Q2 may in particular be deployed on a single chip or die.

The functional unit may be based on a structure, in particular an area on the device. The area may comprise at least one of the following: a gate-source area, a base-emitter area, an IGBT cell, an IGBT stripe, etc. Also, combinations of the above may also be used as an area.

According to FIG. 7, the gate of the IGBT Q1 is connected with the gate of the IGBT Q2. The collectors of the IGBTs Q1 and Q2 are connected and are further connected to a load R2. The emitter of the IGBT Q1 is connected via a resistor R4 (sense resistor) to ground. The emitter of the IGBT Q2 is connected to ground. The gate of the IGBT Q1 is controlled via a voltage source V1 and a resistor R1 and the load R2 are further connected via an inductor L to a voltage source V2. The voltage sources V1 and V2 as well as the load R2 in combination with the inductor L are only exemplary elements of a circuitry in which the unit 701 can be used. The combination of the load R2 and the inductor L are also referred to as an R-L-load.

The resistor R3 may be realized as a temperature compensating element, which shows an increase in resistance with an increase in temperature. Hence, a voltage that can be determined at a node between the resistors R3 and R4, i.e. as voltage across the resistor R4, which is proportional to the current flowing through the current sense resistor R4, is substantially unbiased by variations of temperature.

The resistor R4 may in particular be deployed separately from the unit 701, in particular external to a chip that comprises the unit 701.

The resistor R3 may be integrated together with the IGBTs Q1 and Q2 in the unit 701. The temperature coefficient of the resistor R3 may be positive, substantially linear (corresponding in particular to the temperature coefficient of the voltage between the collector and the emitter of the IGBT Q1) and preferably large.

Advantageously, the temperature coefficient of the resistor may be at least +60% over 100K. For example, the resistor R3 may comprise, e.g., nickel (67% over 100K). It may have a resistance value in the range between 1 Ohm and 10 Ohm at a temperature of 25° C. The accuracy of the resistor R3 may be as high as possible, in particular better than 5%. The resistor R3 may also comprise, e.g., aluminum, doped poly-silicon, beryllium (100% over 100K), titanium, titanium-nitride, tungsten, titanium-tungsten, tantalum, tantalum-nitride and/or copper. It is noted that the resistor R3 may in particular comprise a material that can be used as the barrier layer.

When the IGBT's temperature increases, the collector-emitter saturation voltage V_{CEsat} increases. When the MOSFET's temperature increases, the drain-source voltage increases due to an increasing resistance R_{DSon}.

This resistor R3 may carry the sense current (e.g., up to 100 mA). Hence, the resistor R3 may be adjusted accordingly. In addition, a current sense ratio may be adjusted, e.g., via functional units of the transistors Q1 and Q2 to reduce the sense current amount and to hence avoid any overload situation at the resistor R3. For example, the functional units of the transistors Q1 and Q2 may differ at a ratio of 1:10000 (with the transistor Q1 having the smaller amount of functional units) in order to allow for a small sense current compared to the current flowing through the load and the transistor Q2.

As an example, the resistor R3 may be implemented as a resistive element, e.g., a resistive layer on a chip. The resistive element may comprise aluminum, nickel, tungsten, iron etc. The resistive element is preferably in close proximity to the transistor Q1. The resistive element can be a locally concentrated element or somewhat distributed across the circuitry.

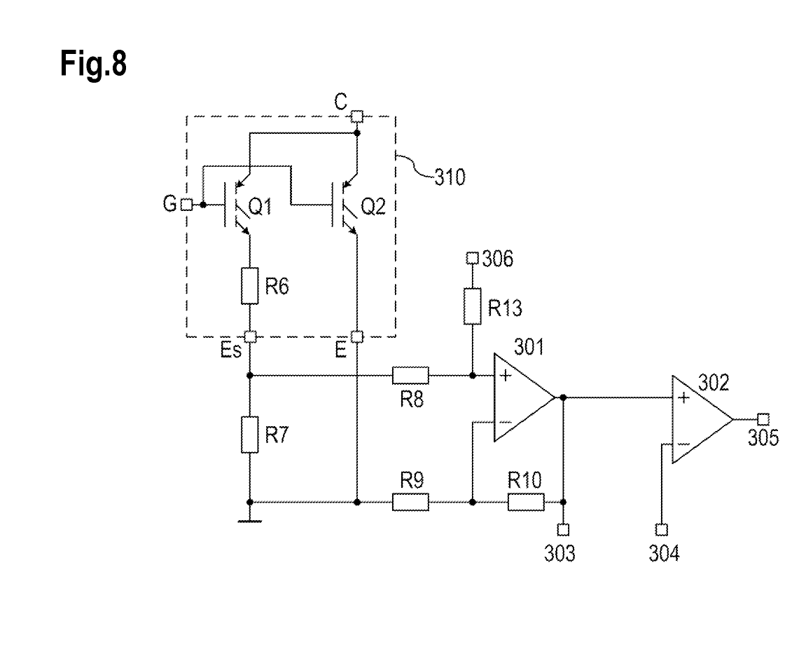

FIG. 8 shows a schematic diagram comprising a unit 310 (which may be similar or identical to the unit 701 shown in FIG. 7) with two transistors Q1 and Q2 and a resistor R6 as a temperature dependent device. The resistor R6 may have a positive temperature coefficient and it may be embedded together with the transistors Q1 and Q2. The transistors Q1 and Q2 may be IGBTs or MOSFETs deployed on the same piece of silicon. The unit 310 comprises
a gate terminal G that is connected to the gate of the transistor Q1 and to the gate of the transistor Q2,
a collector terminal C that is connected to the collector of the transistor Q1 and to the collector of the transistor Q2,
a sense emitter terminal Es that is connected via the resistor R6 to the emitter of the transistor Q1 and
a emitter terminal E that is connected to the emitter of the transistor Q2.

The sense emitter terminal Es is connected via a resistor R7 to ground and via a resistor R8 to the non-inverting input of an operational amplifier 301. The non-inverting input of the operational amplifier 301 is connected via a resistor R13 to a node 306. The emitter terminal E is connected to ground. Also, the emitter terminal E is connected via a resistor R9 to the inverting input of the operational amplifier 301. The inverting input of the operational amplifier 301 and its output are connected via a resistor R10. The output of the operational amplifier 301 is connected to a node 303.

The output of the operational amplifier 301 is further connected to a first input of a comparator 302 (e.g., the non-inverting input of a second operational amplifier) and a node 304 is connected to the second input of the comparator 302 (e.g., the inverting input of the second operational amplifier). The output of the comparator 302 is connected to a node 305.

The nodes indicated in FIG. 8, e.g., nodes 303 to 306, may be realized as connection points, e.g., pins or terminals.

A voltage across the resistor R7 is proportional to the current supplied via the sense emitter terminal Es. A reference voltage may be provided at the node 306 and the node 303 may be connected to an analog-to-digital converter (ADC) or a microcontroller for further processing. The resistors R10 and R13 may be used as feedback resistors and the resistors R8 and R9 are input resistors for the operational amplifier 301.

An adjustable of a predetermined over-current threshold voltage may be applied via the node 304 to the comparator 302. The node 305 may be connected to an error logic or a microcontroller for further processing. Such further processing may comprise at least one of the following: setting a warning flag, increasing an error counter, turning off the transistor for which an over-current has been determined, turning off at least one additional transistor.

At the emitter terminal E, a load current in the range of 50 A to 500 A may be provided, whereas at the sense emitter terminal Es a faction of the load current, i.e. a sense current in the range from 1 mA to 100 mA may be provided. The fraction between these currents may amount to 1:1000 or 1:5000. It is noted that these figures are examples. Accordingly, different amounts of current and/or fractions may be utilized.

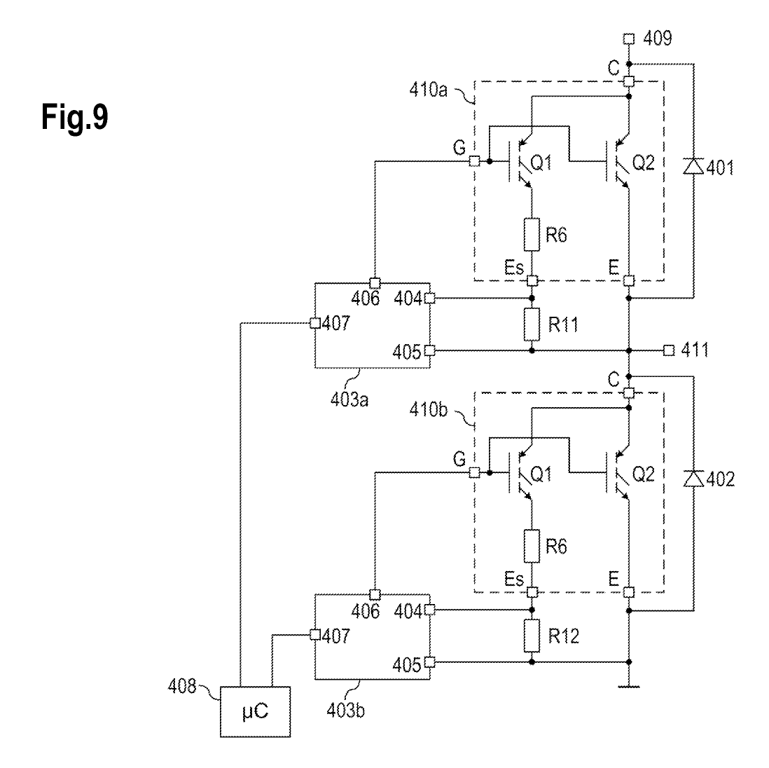

FIG. 9 shows a circuitry of an IGBT half-bridge arrangement comprising a high-side unit 410a and a low-side unit 410b. The units 410a and 410b may have the same structure as unit 310 shown in FIG. 8.

A node 409 is connected to the collector terminal C of the unit 410a, the emitter terminal E of the unit 410a is connected to the collector terminal C of the unit 410b and the emitter terminal E of the unit 410b is connected to ground. A high-side diode 401 is connected across the collector terminal C and the emitter terminal E of the unit 410a, wherein the cathode of the diode 401 is directed towards the collector terminal C. A low-side diode 402 is connected across the collector terminal C and the emitter terminal E of the unit 410b, wherein the cathode of the diode 402 is directed towards the collector terminal C.

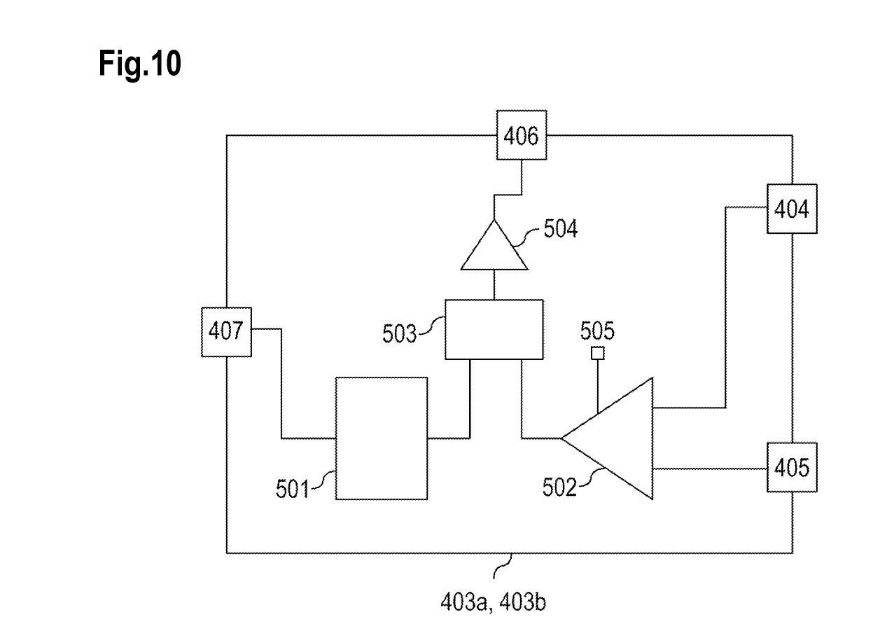

FIG. 9 shows a high-side driver 403a and a low-side driver 403b, which may have the same structure. An exemplary implementation of the drivers 403a and 403b is shown in and explained in more detail with regard to FIG. 10. Each of the drivers 403a and 403b comprises terminals 404 to 407.

The gate terminal G of the unit 410a is connected to the terminal 406 of the driver 403a. The sense emitter terminal Es of the unit 410a is connected to the terminal 404 of the driver 403a. The emitter terminal E of the unit 410a is connected to the terminal 405 of the driver 403a. A resistor R11 (sense resistor) is connected between the terminals 404 and 405 of the driver 403a. The terminal 407 of the driver 403a is connected to a microcontroller 408. The gate terminal G of the unit 410b is connected to the terminal 406 of the driver 403b. The sense emitter terminal Es of the unit 410b is connected to the terminal 404 of the driver 403b. The emitter terminal E of the unit 410b is connected to the terminal 405 of the driver 403b. A resistor R12 (sense resistor) is connected between the terminals 404 and 405 of the driver 403b. The terminal 407 of the driver 403b is connected to the microcontroller 408.

A node 411 connected to the emitter terminal E of the unit 410a and to the collector terminal C of the unit 410b may be connected to a load, e.g., a single phase of a three phase generator.

FIG. 10 shows a schematic of the driver 403a, 403b comprising the terminals 404 to 407. The terminal 404 is connected to the first input of a comparator 502 and the terminal 405 is connected to the second input of the comparator 502. Hence, a voltage sensed at the resistors R11 (in case of the driver 403a) and R12 (in case of the driver 403b) may be compared with an (adjustable or predetermined) over-current threshold voltage 505 and the result of such comparison is fed to a control unit 503.

The microcontroller 408 controls the driver 403a, 403b via its terminal 407, which is connected to the control unit 503 via a galvanic isolation 501. Such galvanic isolation 501 can be realized as an optocoupler, a transformer or any galvanically isolating element. It enables controlling the respective unit 410a, 410b by the microcontroller 408, wherein the microcontroller 408 in this example of FIG. 9 has ground as a reference potential and the gate terminals G of the units 410a, 410b may have different (floating) reference potentials (other than ground).

The control unit 503 provides an output signal via a driver 504 to the terminal 406, which is connected to the gate terminals of the units 410a and 410b.

The node 409 may be connected to a high DC voltage, e.g., 400V. As an alternative to the example shown in FIG. 9, a MOSFET half-bridge could be used for a DC/DC converter using lower input voltages, e.g., 14V. In such scenario, the gates of the transistors may be operated via a single driver and/or microcontroller. No galvanic separation of high-side switch and low-side switch is required.

The examples suggested herein may in particular be based on at least one of the following solutions. In particular combinations of the following features could be utilized in order to reach a desired result. The features of the method could be combined with any feature(s) of the device, apparatus or system or vice versa.

An integrated temperature sensor is provided, said sensor comprising:
a barrier layer connecting at least two conductive elements,
wherein the barrier layer has a positive temperature coefficient.

The integrated temperature sensor may also be referred to as temperature sensor (or sensor) or temperature sensing means. The integrated temperature sensor may be arranged in a semiconductor device for measuring the temperature with high accuracy.

The barrier layer may in particular be a barrier that hinders diffusion, e.g., a diffusion between adjacent layers. Also, the barrier layer may be provided for stress compensating purposes (in particular between adjacent layers). The barrier layer may have a thickness in the range of, e.g., 50 nm to 300 nm.

The barrier layer may in particular comprises several (thin) layers. These several layers may be identical or different types of layers. The several layers of the barrier layer may (at least partially) serve different purposes, e.g., diffusion, stress compensation, etc.

Hence, the barrier layer of the integrated temperature sensor has a varying resistance value over a varying temperature. The thickness of the barrier layer may also be used to adjust the resistance value. Hence, the integrated temperature sensor can be used as an electronic component that varies over temperature; a voltage across the integrated temperature sensor or a current through the integrated temperature sensor can be used to determine the temperature with high accuracy.

Such temperature-dependent voltage or current may also be used for temperature compensating purposes.

In an embodiment, the conductive element is a conductive pad or a conductive layer or a part thereof.

In an embodiment, the barrier layer comprises at least one of the following
nickel;
aluminum;
iron;
permalloy;
beryllium;
titanium;
titanium-nitride;
tungsten;
titanium-tungsten;
tantalum;
tantalum-nitride;
copper.

Also, the sensor may comprise combinations of these elements.

In an embodiment, the at least two conductive elements are arranged on top of the barrier layer.

In an embodiment, the sensor is integrated in a semiconductor device.

The sensor may in particular be integrated into a power semiconductor device.

In an embodiment, the semiconductor device is one of the following:
a transistor;
a MOSFET;
an IGBT;
a JFET;
a diode;
a vertical element.

The vertical element may have two terminals on opposing sides, wherein the current flows from one side to the other side.

A circuit is provided, said circuit comprising
an electronic switching element,
an integrated temperature sensor, which is arranged in the vicinity of the electronic switching element,
wherein the integrated temperature sensor comprises
   a barrier layer connecting at least two conductive elements,
   wherein the barrier layer has a positive temperature coefficient.

The electronic switching element can be any transistor, e.g., MOSFET, JFET or IGBT, or diode. The electronic switching element may comprise at least one transistor. The integrated temperature sensor may be used for temperature measurement purposes or for compensating variations in current or voltage sensing that are based on changes in temperature. It is noted that the integrated temperature sensor may in particular mitigate the effects that are based on temperature changes, but does not have to fully compensate such effects.

In an embodiment, the integrated temperature sensor is embedded in the electronic switching element.

In an embodiment, the integrated temperature sensor is connected in series in a current path of the electronic switching element.

The current path may be a path comprising the collector and emitter of an IGBT or source and drain of a MOSFET.

In an embodiment, the electronic switching element comprises at least one transistor, in particular at least one IGBT and/or at least one MOSFET.

In an embodiment, the electronic switching element comprises at least two transistors sharing a common functional unit.

In an embodiment,
the electronic switching element comprises a first transistor and a second transistor,
the first transistor and the second transistor are located on the same chip,
the first transistor and the second transistor are connected in parallel such that the first transistor carries a current that is proportional to the current carried by the second transistor,
the integrated temperature sensor is connected in series in a current path of the first transistor.

In an embodiment,
the electronic switching element comprises a first transistor and a second transistor,
the first transistor and the second transistor are located on the same substrate,
a functional unit of the first transistor is smaller than a functional unit of the second transistor,
the first transistor is connected in series with the integrated temperature sensor,
the gate of the first transistor is connected to the gate of the second transistor,
the collector of the first transistor is connected to the collector of the second transistor.

Hence, the first transistor may be regarded as current sense field, which allows the current sensed via the integrated temperature sensor (as a temperature compensating element) to be significantly smaller than the current through a load. This efficiently reduces losses and increases the efficiency of the circuit.

In an embodiment, the first transistor and the second transistor share a functional unit, wherein the smaller portion of the functional unit is used for the first transistor.

This is exemplary for an IGBT type transistor. In case of a MOSFET or JFET, the collector corresponds to the drain and the emitter corresponds to the source.

In an embodiment, the circuit is arranged on a single chip or die, in particular part of an integrated circuit.

A method for manufacturing an integrated temperature sensor is suggested, the method comprising:
structuring a barrier layer that connects at least two conductive elements, wherein the barrier layer has a positive temperature coefficient.

In an embodiment, structuring the barrier layer comprises:
masking the at least two conductive elements of a conductive layer;
removing the conductive layer except for the at least two conductive elements masked;
masking the at least two conductive elements and a portion of underlying barrier layer that connects the at least two conductive elements;
removing the barrier layer except for the at least two conductive elements and the portion of the barrier layer that were masked.

In an embodiment, masking comprises applying a photo resist.

In an embodiment, removing comprises an etching process and wherein the photo resist is removed after the etching process.

In an embodiment, structuring the barrier layer comprises:
applying the barrier layer to connect at least two conductive elements;
applying a conductive layer;
masking the at least two conductive elements of the conductive layer;
removing the conductive layer except for the at least two conductive elements masked.

Hence, a conductive layer may be applied on top of the barrier layer, which may have already been structured for the at least two conductive elements to be connected via the barrier layer.

Although various exemplary embodiments have been disclosed, it will be apparent to those skilled in the art that various changes and modifications can be made which will achieve some of the advantages of this disclosure without departing from the spirit and scope of this disclosure. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of this disclosure may be achieved in either all software implementations, using the appropriate processor instructions, or in hybrid implementations that utilize a combination of hardware logic and software logic to achieve the same results. Such modifications to the inventive concept are intended to be covered by the appended claims.

1. An integrated temperature sensor comprising:
a barrier layer connecting at least two conductive elements,
wherein the barrier layer has a positive temperature coefficient.

2. The sensor according to claim 1, wherein the conductive element is a conductive pad or a conductive layer or a part thereof.

3. The sensor according to claim 1, wherein the barrier layer comprises at least one of the following
nickel;
aluminum;
iron;
permalloy;
beryllium;
titanium;
titanium-nitride;
tungsten;
titanium-tungsten;
tantalum;
tantalum-nitride; and
copper.

4. The sensor according to claim 1, wherein the at least two conductive elements are arranged on top of the barrier layer.

5. The sensor according to claim 1, wherein the sensor is integrated in a semiconductor device.

6. The sensor according to claim 5, wherein the semiconductor device is one of the following:
a transistor;
a MOSFET;
an IGBT;
a JFET;
a diode;
a vertical element.

7. A circuit comprising:
an electronic switching element, and
an integrated temperature sensor, wherein the integrated temperature sensor is arranged in the vicinity of the electronic switching element,
wherein the integrated temperature sensor includes:
a barrier layer connecting at least two conductive elements,
wherein the barrier layer has a positive temperature coefficient.

8. The circuit according to claim 7, wherein the integrated temperature sensor is embedded in the electronic switching element.

9. The circuit according to claim 7, wherein the integrated temperature sensor is connected in series in a current path of the electronic switching element.

10. The circuit according to claim 7, wherein the electronic switching element comprises at least one transistor, in particular at least one IGBT and/or at least one MOSFET.

11. The circuit according to claim 7, wherein the electronic switching element comprises at least two transistors sharing a common functional unit.

12. The circuit according to claim 7,
wherein the electronic switching element comprises a first transistor and a second transistor,
wherein the first transistor and the second transistor are located on the same chip,
wherein the first transistor and the second transistor are connected in parallel such that the first transistor carries a current that is proportional to the current carried by the second transistor,
wherein the integrated temperature sensor is connected in series in a current path of the first transistor.

13. The circuit according to claim 7,
wherein the electronic switching element comprises a first transistor and a second transistor,
wherein the first transistor and the second transistor are located on the same substrate,
wherein a functional unit of the first transistor is smaller than a functional unit of the second transistor,
wherein the first transistor is connected in series with the integrated temperature sensor,
wherein the gate of the first transistor is connected to the gate of the second transistor,
wherein the collector of the first transistor is connected to the collector of the second transistor.

14. The circuit according to claim 13, wherein the first transistor and the second transistor share a functional unit, wherein the smaller portion of the functional unit is used for the first transistor.

15. The circuit according to claim 7, wherein the circuit is arranged on a single chip or die, in particular part of an integrated circuit.

16. A method for manufacturing an integrated temperature sensor, the method comprising:
structuring a barrier layer that connects at least two conductive elements, wherein the barrier layer has a positive temperature coefficient.

17. The method according to claim 16, wherein structuring the barrier layer comprises:
masking the at least two conductive elements of a conductive layer;
removing the conductive layer except for the at least two conductive elements masked;
masking the at least two conductive elements and a portion of underlying barrier layer that connects the at least two conductive elements; and
removing the barrier layer except for the at least two conductive elements and the portion of the barrier layer that were masked.

18. The method according to claim 17, wherein masking comprises applying a photo resist.

19. The method according to claim 18, wherein removing comprises an etching process and wherein the photo resist is removed after the etching process.

20. The method according to claim 16, wherein structuring the barrier layer comprises:
applying the barrier layer to connect at least two conductive elements;
applying a conductive layer;
masking the at least two conductive elements of the conductive layer; and
removing the conductive layer except for the at least two conductive elements masked.
